(19) United States
(12) Patent Application Publication
(10) Pub. No.: US 2012/0000523 A1
(43) Pub. Date: Jan. 5, 2012

(54) METAL PASTE COMPOSITION FOR FORMING ELECTRODE AND SILVER-CARBON COMPOSITE ELECTRODE AND SILICON SOLAR CELL USING THE SAME

(75) Inventors: Jong-Wuk Park, Gyeonggi-do (KR); Sang-Ho Kim, Daejeon (KR); So-Won Kim, Daejeon (KR)

(73) Assignee: LG Chem, Ltd., Seoul (KR)

(21) Appl. No.: 12/996,316

(22) PCT Filed: Jun. 3, 2009
(86) PCT No.: PCT/KR2009/002951

§ 371 Date: Sep. 22, 2011

(30) Foreign Application Priority Data
Jun. 4, 2008 (KR) 10-2008-0052501
May 26, 2009 (KR) 10-2009-0046138

(51) Int. Cl. H01L 31/0224; H01B 1/22

(52) U.S. Cl. 136/256; 252/503

(57) ABSTRACT

Provided are a metal paste composition for forming an electrode, and a silver-carbon composite electrode and a silicon solar cell using the same. The metal paste composition for forming an electrode including glass frit powder, silver powder and an organic binder further includes 20 or less parts by weight, preferably 25 or less parts by weight of carbon-based material powder based on 100 parts by weight of the silver powder. Optionally, the silver powder has an average particle size of 1 μm or less. An electrode formed using the metal paste composition does not have a substantial deterioration in its electrical characteristics although the silver content is reduced.

### TECHNICAL FIELD

The present invention relates to a metal paste composition for forming an electrode, and a silver-carbon composite electrode and a silicon solar cell using the same, and more particularly, to a metal paste composition that can be used to economically form an electrode of various circuits or electronic products, a silver-carbon composite electrode formed using the metal paste composition and a silicon solar cell including the electrode.

### BACKGROUND ART

Recently, with development of electronic industry, there is demand for miniaturization and high reliability of electronic products and devices. To meet the demand, various attempts have been made to form circuit patterns or electrodes of electronic products requiring high integration. Under such circumstances, use of a conductive metal paste is the center of interest because it hardly generates by-products or contaminants during a process.

A typical metal paste includes a conductive metal, a glass frit and an organic binder. The conductive metal includes silver, aluminum and so on. Generally, silver is used as a conductive metal. The conductive metal paste is mainly used to mount a hybrid IC or a semiconductor IC, or to form various condensers or electrodes, and recently has the expanded application range to high-tech electronic products such as PCBs, ELs, touch panels, RFIDs, LCDs, PDPs or solar cells. With expansion and development of the related industry, demand for the conductive metal paste is increasing.

In particular, as it is expected that conventional energy sources such as oil or charcoal will be exhausted, interests in alternative energy are increasing. Among alternative energy, a solar cell has abundant energy sources and does not cause an environmental pollution, and thus it becomes the object of attention.

The solar cell is classified into a solar heat cell that produces vapor required to run a turbine using a solar heat, and a solar light cell that converts photons into an electrical energy using properties of a semiconductor. Generally, the solar light cell is represented as a solar cell.

The solar cell largely includes a silicon solar cell, a compound semiconductor solar cell and a tandem solar cell according to the raw material. Among them, the silicon solar cell leads the solar cell market.

FIG. 1 is a cross-sectional view showing a basic structure of a silicon solar cell. Referring to FIG. 1, the silicon solar cell includes a substrate 101 of a p-type silicon semiconductor, and an emitter layer 102 of an n-type silicon semiconductor. A p-n junction is formed at an interface between the substrate 101 and the emitter layer 102 in the similar way to a diode.

When solar light is incident on the solar cell of the above-mentioned structure, electrons and holes create in the silicon semiconductors doped with impurities by the photovoltaic effect. Specifically, electrons create in the emitter layer 102 of an n-type silicon semiconductor as a plurality of carriers and holes create in the substrate 101 of a p-type silicon semiconductor as a plurality of carriers. The electrons and holes created by the photovoltaic effect are drawn toward the n-type silicon semiconductor and p-type silicon semiconductor, and move to a front electrode 103 on the emitter layer 102 and a back electrode 104 below the substrate 101, respectively. Then, the front electrode 103 and the back electrode 104 are connected by a wire, so that the current flows.

A conductive metal paste is used to form a front or back electrode in a solar cell, in addition to various electrodes of other electronic products as mentioned above.

However, silver included generally in the conductive metal paste has good conductivity but high cost, which makes commercialization of products difficult.

Therefore, techniques are needed that can reduce a usage amount of silver while not deteriorating the electrical characteristics of a circuit or electrode formed using a metal paste.

### DISCLOSURE

### Technical Problem

It is an object of the invention to provide a metal paste composition for forming an electrode that does not deteriorates the electrical characteristics of a circuit or electrode although a silver content is low, and a silver-carbon composite electrode and a solar cell using the metal paste composition.

### Technical Solution

In order to accomplish the object, according to an aspect of the present invention, a metal paste composition for forming an electrode including glass frit powder, silver powder and an organic binder, further includes 20 or less parts by weight of carbon-based material powder based on 100 parts by weight of the silver powder. The metal paste composition according to an aspect of the present invention includes a specific content range of carbon-based material, which does not result in deterioration in electrical conductivity of a circuit or electrode although the silver content is reduced.

And, in order to accomplish the object, according to another aspect of the present invention, a metal paste composition for forming an electrode including glass frit powder, silver powder and an organic binder, further includes 25 or less parts by weight of carbon-based material powder based on 100 parts by weight of the silver powder, wherein the silver powder has an average particle size of 1 μm or less. The metal paste composition according to another aspect of the present invention includes a further increased content of carbon-based material and silver powder of a specific average particle size, which does not result in deterioration in electrical conductivity of a circuit or electrode although the silver content is reduced.

In the present invention, the carbon-based material may be, for example, at least one selected from the group consisting of graphite, carbon black, acetylene black, denka black, ketjen black, activated carbon, mesoporous carbon, carbon nano tube, carbon nano fiber, carbon nano horn, carbon nano ring, carbon nano wire, fullerene (C60) and Super-P, however the present invention is not limited in this regard.

In order to accomplish the object, the present invention also provides a silver-carbon composite electrode formed by sintering the metal paste composition of the present invention.

In the silver-carbon composite electrode according to the present invention, a weight ratio of silver and carbon in the electrode is silver:carbon=1:0.001 to 1:0.25, however the present invention is not limited in this regard.

The metal paste composition of the present invention may be used to form a front electrode of a silicon solar cell.

### DESCRIPTION OF DRAWINGS

These and other features, aspects, and advantages of preferred embodiments of the present invention will be more fully described in the following detailed description, taken accompanying drawings.

FIG. 1 is a schematic cross-sectional view of a silicon solar cell according to the prior art.

FIG. 2 is a cross-sectional SEM image of an electrode formed using a metal paste composition prepared according to example 1 of the present invention.

FIG. 3 is a cross-sectional SEM image of an electrode formed using a metal paste composition prepared according to example 2 of the present invention.

FIG. 4 is a cross-sectional SEM image of an electrode formed using a metal paste composition prepared according to comparative example 1.

FIG. 5 is a cross-sectional SEM image of an electrode formed using a metal paste composition prepared according to comparative example 2.

FIG. 6 is a cross-sectional SEM image of a silver-carbon composite electrode formed according to example 11 of the present invention.

FIG. 7 is a graph illustrating conductivity of electrodes formed according to examples 1 to 5 of the present invention and comparative example 1.

FIG. 8 is a graph illustrating conductivity of electrodes formed according to examples 11 to 14 of the present invention, with the graph of FIG. 7 for comparison.

FIG. 9 is a cross-sectional view of a silicon solar cell according to an embodiment of the present invention.

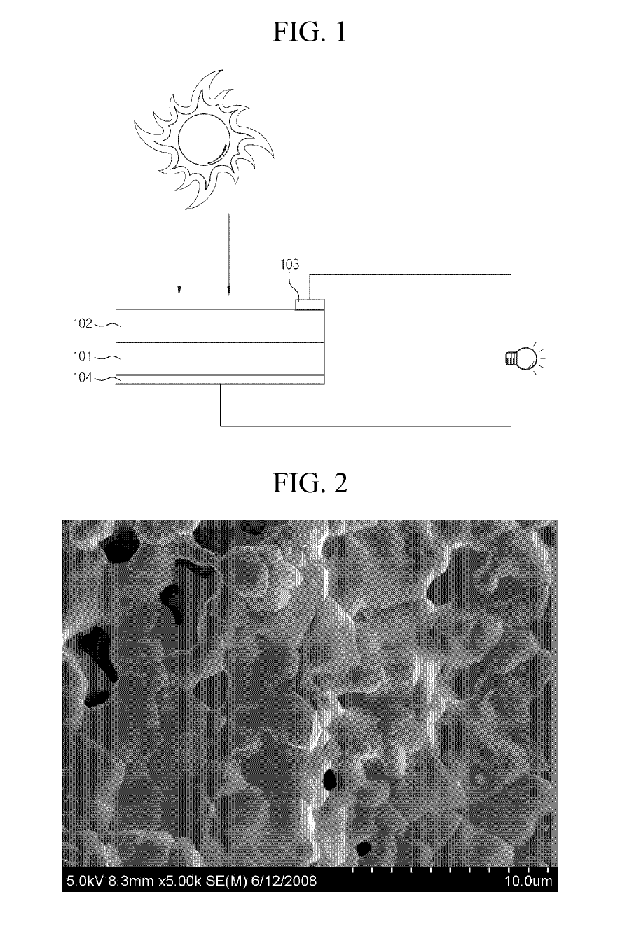

### MODE FOR INVENTION

Hereinafter, the present invention will be described in detail with reference to the accompanying drawings. Prior to the description, it should be understood that the terms used in the specification and appended claims should not be construed as limited to general and dictionary meanings, but interpreted based on the meanings and concepts corresponding to technical aspects of the present invention on the basis of the principle that the inventor is allowed to define terms appropriately for the best explanation.

A metal paste composition of the present invention may be used in the same field as a typical conductive metal paste, for example, to mount a hybrid IC, a semiconductor IC and so on, or in various condensers, electrodes or the like, and in particular, as an electrode material for PCB, EL, a touch panel, RFID, LCD, PDP, a solar cell, a heating glass and so forth, however the present invention is not limited in this regard.

The metal paste composition according to an embodiment of the present invention includes glass frit powder, silver powder and an organic binder as mentioned above, and in particular, further includes a specific amount of carbon-based material powder. In the metal paste composition, the carbon-based material powder may be partially substituted for silver (Ag). This leads to reduction in a usage amount of silver, but does not result in deterioration in electrical conductivity of a circuit or electrode to be subsequently formed.

And, the inventors of the present invention found that when a metal paste composition including glass frit powder, silver powder, an organic binder and carbon-based material powder according to the present invention has a controlled average particle size of the silver powder, an electrode formed using the metal paste composition does not have a deterioration in electrical conductivity although the content of the carbon-based material is increased.

The carbon-based material that can be used in the present invention is not limited to a specific type if it has conductive properties. For example, the carbon-based material may be at least one selected from the group consisting of graphite, carbon black, acetylene black, denka black, ketjen black, activated carbon, mesoporous carbon, carbon nano tube, carbon nano fiber, carbon nano horn, carbon nano ring, carbon nano wire, fullerene (C60) and Super-P, however the present invention is not limited in this regard.

In an embodiment where the metal paste composition of the present invention includes silver powder of a non-controlled, typical average particle size, the carbon-based material is preferably included at an amount of 20 parts by weight or less based on 100 parts by weight of the silver powder. If the carbon-based material is included more than 20 parts by weight, an electrode formed using the metal paste composition has an excessively high specific resistance and cannot work as a suitable electrode. Once the carbon-based material of the present invention is included in the metal paste composition, effects pursued by the present invention can be obtained. Thus, the content of the carbon-based material does not have a specific minimum limit. For example, the minimum limit of content of the carbon-based material may be 1 part by weight, preferably 0.1 parts by weight based on 100 parts by weight of the silver powder, however the present invention is not limited in this regard.

In another embodiment where the metal paste composition of the present invention includes silver powder of a controlled average particle size, the carbon-based material is preferably included at an amount of 25 parts by weight or less based on 100 parts by weight of the silver powder. If the carbon-based material is included more than 25 parts by weight, an electrode formed using the metal paste composition has an excessively high specific resistance and cannot work as a suitable electrode. As mentioned above, once the carbon-based material of the present invention is included in the metal paste composition, effects pursued by the present invention can be obtained. Thus, the content of the carbon-based material does not have a specific minimum limit. For example, the minimum limit of content of the carbon-based material may be 1 part by weight, preferably 0.1 parts by weight based on 100 parts by weight of the silver powder, however the present invention is not limited in this regard.

In the embodiment of the metal paste composition including silver powder of a controlled average particle size, an average particle size of the silver powder is 1 μm or less. If an average particle size of the silver powder is not in the above range, a maximum limit of content of the carbon-based material for favorably maintaining the performance of an electrode is lower than the required maximum limit in the present invention.

When an average particle size of the silver powder is within the above range, an electrode formed using a conductive paste including a carbon-based material does not have a deterioration in electrical characteristics. Moreover, although the total weight of the carbon-based material included in the conductive paste is equal to the total weight of silver powder, the electrode does not have a substantial deterioration in electrical characteristics. If the silver powder of the present invention has an average particle size of 1 μm or less, effects pursued by the present invention can be obtained, and thus the average particle size of the silver powder does not have a specific minimum limit. In consideration of the convenience of handling or the like, the average particle size of the silver powder may be 0.01 to 1 μm, preferably 0.1 to 1 μm, however the present invention is not limited in this regard.

Optionally, the metal paste composition according to the present invention may further include a conductive metal component that is typically used in the art. For example, the conductive metal component may be at least one selected from the group consisting of copper, aluminium and oxides thereof. The conductive metal component can further provide the required properties.

The glass frit powder that can be used in the present invention is not limited to a specific type if it is used in the art. For example, the glass frit powder may include lead oxide and/or bismuth oxide. Specifically, the glass frit powder may be at least one selected from the group consisting of SiO₂—PbO based powder, SiO₂—PbO—B₂O₃ based powder and Bi₂O₃—B₂O₃—SiO₂ based powder, however the present invention is not limited in this regard.

The organic binder included in the metal paste composition of the present invention makes a mixture of the silver powder, the carbon-based material, the glass frit powder and optionally the conductive metal component into a paste phase. The organic binder used in the present invention is not limited to a specific type if it is used to prepare a metal paste composition in the art. For example, the organic binder may be at least one selected from the group consisting of cellulose, butyl carbitol and terpineol, however the present invention is not limited in this regard.

The contents of the glass frit powder and the organic binder may be selected variously according to the specific purpose of use of the metal paste composition. For example, the glass frit powder is preferably included at an amount of 1 to 20 parts by weight based on 100 parts by weight of the silver powder. And, the organic binder is preferably included at an amount of 5 to 30 parts by weight based on 100 parts by weight of the silver powder.

The above content ranges of the glass frit powder and the organic binder allow easy formation of an electrode and preparation of a paste of viscosity advantageous to screen printing, providing a suitable aspect ratio for preventing the paste from flowing down after screen printing.

The above components are uniformly mixed by various methods that are known in the art, to obtain the metal paste composition according to the present invention.

And, the present invention provides a silver-carbon composite electrode by applying the metal paste composition of the present invention on a predetermined substrate proper to the required purpose of use, and sintering the metal paste composition.

In the silver-carbon composite electrode of the present invention, a carbon component near the surface of the electrode reacts with oxygen in the air during the sintering process, to form gas such as carbon dioxide or the like, and then the carbon component disappears. So, the carbon component does not substantially exist on the surface of the electrode that is exposed to an external environment. Thus, the external part of the electrode exhibits an intrinsic color of a typical silver electrode, and the carbon-based material is dispersed only in the electrode.

And, there is no significant difference in specific resistance at the surface between the silver-carbon composite electrode of the present invention and a typical silver electrode. For example, a specific resistance of the silver-carbon composite electrode of the present invention may be 5 to 15 μΩ/cm, however the present invention is not limited in this regard.

Because a portion of carbon component disappears during manufacturing the silver-carbon composite electrode of the present invention, a weight ratio of silver and carbon in the silver-carbon composite electrode is different from that in the paste. The weight ratio of silver and carbon in the silver-carbon composite electrode may vary according to sintering temperature, sintering time and so on, for example, silver:carbon=1:0.001 to 1:0.25, however the present invention is not limited in this regard.

A suitable sintering temperature for obtaining the silver-carbon composite electrode of the present invention may be a sintering temperature applied typically to a conductive paste. For example, the sintering temperature may be 500 to 960° C., however, the present invention is not limited in this regard.

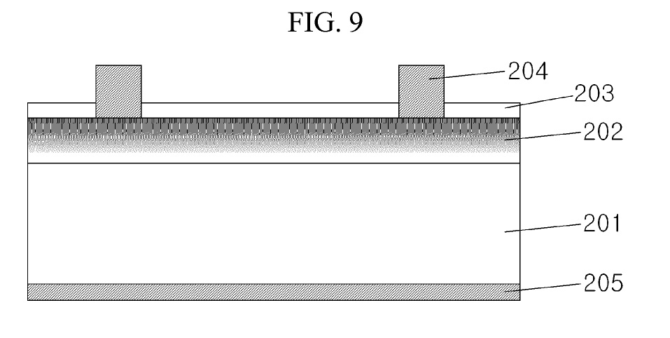

Hereinafter, an example of a silicon solar cell using the metal paste composition of the present invention is described with reference to FIG. 9. However, it is obvious that the metal paste composition may be used to other various electrical materials or electronic devices and products as mentioned above. And, it should be understood that the terms used in the specification and appended claims should not be construed as limited to general and dictionary meanings, but interpreted based on the meanings and concepts corresponding to technical aspects of the present invention on the basis of the principle that the inventor is allowed to define terms appropriately for the best explanation.

FIG. 9 is a cross-sectional view of a silicon solar cell according to an embodiment of the present invention.

Referring to FIG. 9 the silicon solar cell according to the present invention includes a silicon semiconductor substrate 201, an emitter layer 202 formed on the substrate 201, an antireflection film 203 formed on the emitter layer 202, a front electrode 204 connected to an upper surface of the emitter layer 202 and a back electrode 205 connected to a back surface of the substrate 201.

The substrate 201 may be doped with a Group 3 element in the periodic table, for example, B, Ga, In and so on, as a p-type impurity. The emitter layer 202 may be doped with a Group 5 element in the periodic table, for example, P, As, Sb and so on, as an n-type impurity. When the substrate 201 and emitter layer 202 are doped with opposite conductivity type impurities as mentioned above, a p-n junction is formed at an interface between the substrate 201 and the emitter layer 202. Meanwhile, a p-n junction may be formed at an interface between the substrate 201 doped with an n-type impurity and the emitter layer 202 doped with a p-type impurity.

The antireflection film 203 passivates a defect (for example, a dangling bond) that exists on the surface of or in the bulk of the emitter layer 202 and reduces the incident light on a front surface of the substrate 201. If a defect of the emitter layer 202 is passivated, a recombination site of a hydrophobic carrier is removed to increase an open-circuit voltage of the solar cell. And, as solar reflectivity decreases, an amount of light reaching the p-n junction increases and then a short-circuit current of the solar cell increases. Accordingly, a conversion efficiency of the solar cell increases as much as increases in the open-circuit voltage and the short-circuit current of the solar cell.

The antireflection film 203 may have, for example, a monolayered or multilayered structure of at least one material selected from the group consisting of a silicon nitride film, a silicon nitride film including hydrogen, a silicon oxide film, a silicon oxide nitride film, MgF₂, ZnS, MgF₂, TiO₂ and CeO₂, however the present invention is not limited in this regard. And, the antireflection film 203 may be formed by vacuum deposition, chemical vapor deposition, spin coating, screen printing or spray coating, however the present invention is not limited in this regard.

The front and back electrodes 204 and 205 are metal electrodes made from silver and aluminium, respectively. As mentioned above, the front electrode 204 is formed using the metal paste composition of the present invention. The silver electrode 204 has a high electrical conductivity. The aluminium electrode 205 also has a high electrical conductivity, in addition to a high affinity for the substrate 201 made from a silicon semiconductor, providing good bondability with the substrate 201.

The front and back electrodes 204 and 205 may be formed by various well-known techniques, but is preferably formed by screen printing. Specifically, the front electrode 204 is formed by applying the metal paste composition of the present invention on a front electrode forming area by screen printing, and performing a thermal treatment. Then, the formed front electrode 204 is connected to the emitter layer 202 by a punch through across the antireflection film 203.

Similarly, the back electrode 205 is formed by applying a back electrode paste including aluminium, quartz silica and a binder on the back surface of the substrate 201 by screen printing, and performing a thermal treatment. During the thermal treatment, aluminium of the back electrode paste is dispersed through the back surface of the substrate 201, so that a back surface field (BSF) (not shown) layer may be formed at an interface between the back electrode 205 and the substrate 201. The BSF layer prevents a carrier from moving to the back surface of the substrate 201 and recombining with the substrate 201. Thereby, an open-circuit voltage and fidelity increase, and a conversion efficiency of the solar cell increases.

Hereinafter, the preferred embodiments of the present invention are described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

### Examples 1 to 5

According to the content of Table 1, silver powder, Bi₂O₃ based glass frit powder and carbon black were uniformly mixed and agitated, added with an organic binder including cellulose, butyl carbitol and terpineol at 2:5:5 weight ratio, and agitated to prepare a metal paste composition.

### Examples 6 to 10

A metal paste composition was prepared in the same way as example 1, except that graphite was added instead of carbon black.

### Comparative Examples 1 and 2

A metal paste composition was prepared in the same way as example 1, except that a content of carbon black was not in the range of the present invention.

### Comparative Examples 4 to 6

A metal paste composition was prepared in the same way as example 2, except that a content of graphite was not in the range of the present invention.

TABLE 1

| | | | | | Organic |
|---|---|---|---|---|---|
| D | Silver | Carbon-based material | | Glass frit | binder |
| Example 1 | 100 | Carbon | 0.5 | 10 | 20 |
| Example 2 | 100 | black | 1.0 | 10 | 20 |
| Example 3 | 100 | | 5.0 | 10 | 20 |
| Example 4 | 100 | | 10.0 | 10 | 20 |
| Example 5 | 100 | | 20.0 | 10 | 20 |
| Example 6 | 100 | Graphite | 0.5 | 10 | 20 |
| Example 7 | 100 | | 1.0 | 10 | 20 |
| Example 8 | 100 | | 5.0 | 10 | 20 |
| Example 9 | 100 | | 10.0 | 10 | 20 |
| Example 10 | 100 | | 20.0 | 10 | 20 |
| Comparative | 100 | Carbon | 25.0 | 10 | 20 |
| example 1 | | black | | | |
| Comparative | 100 | | 30.0 | 10 | 20 |
| example 2 | | | | | |
| Comparative | 100 | Graphite | 25.0 | 10 | 20 |
| example 3 | | | | | |
| Comparative | 100 | | 30.0 | 10 | 20 |
| example 4 | | | | | |

* Unit is part by weight
* Silver of examples 1 to 10 and comparative examples 1 to 4 has an average particle size of about 3 μm.

### Examples 11 to 14

According to the content of Table 2, silver powder, Bi₂O₃ based glass frit powder and carbon black are uniformly mixed and agitated, added with an organic binder including cellulose, butyl carbitol and terpineol at 2:5:5 weight ratio, and agitated to prepare a metal paste composition.

TABLE 2

| D | Silver | Carbon black | Glass frit | Solvent |
|---|---|---|---|---|
| Example 11 | 100 | 0.5 | 10 | 20 |
| Example 12 | 100 | 1.0 | 10 | 20 |
| Example 13 | 100 | 10.0 | 10 | 20 |
| Example 14 | 100 | 25.0 | 10 | 20 |

* Unit is part by weight
* Silver of examples 11 to 14 has an average particle diameter of about 0.8 μm.

### Test Example

### Evaluation of Sintered Structure

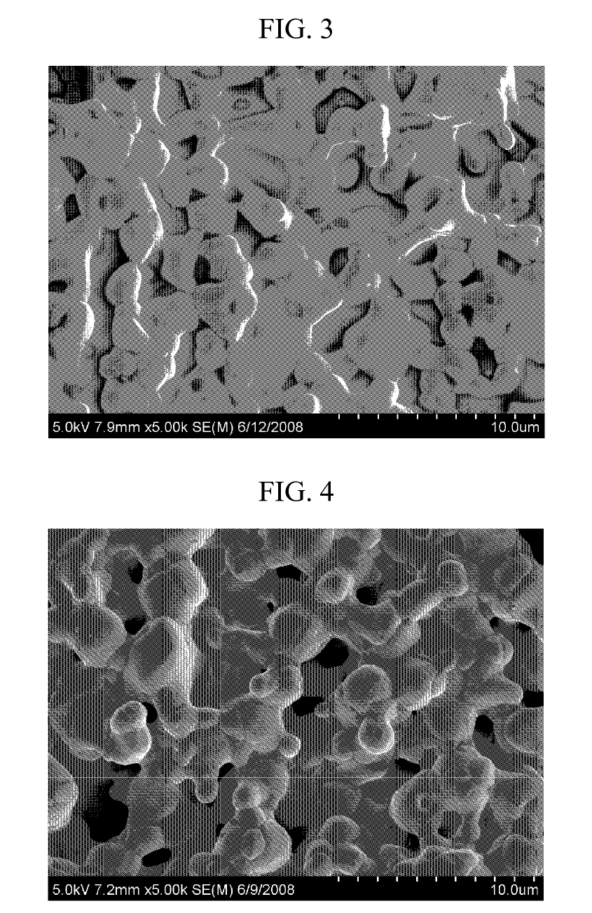

FIGS. 2 to 5 shows SEM images of electrodes formed by sintering metal paste compositions according to example 11, example 12, example 1 and example 2, respectively. Referring to FIGS. 2 to 5, the sintered structures shown in FIGS. 2 and 3 are denser than the sintered structures shown in FIGS. 4 and 5.

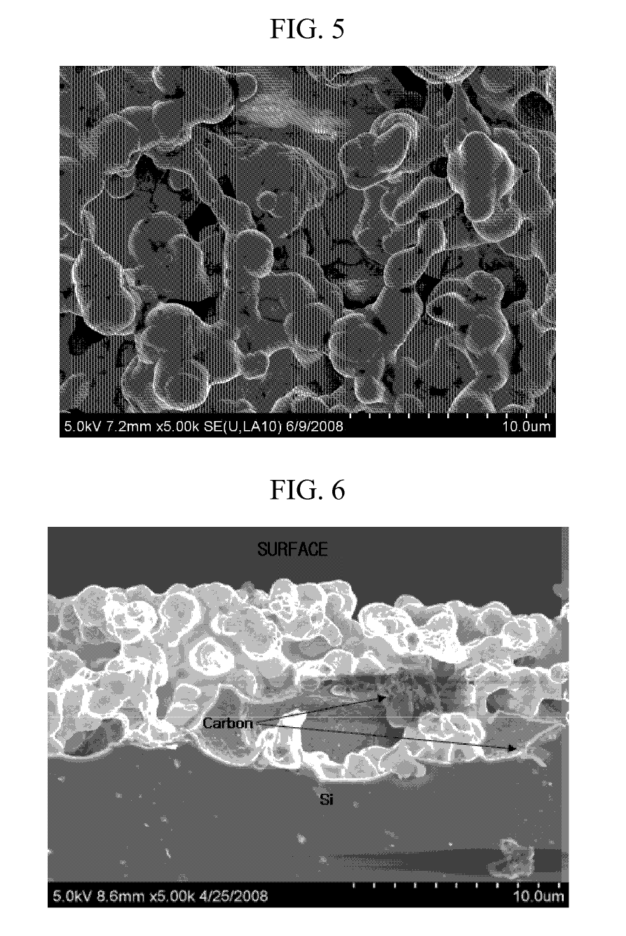

And, FIG. 6 is a cross-sectional SEM image of a silver-carbon composite electrode formed according to example 11 of the present invention. Referring to FIG. 6, a carbon-based material does not remain on the surface of the electrode, but is dispersed in the electrode.

### Test Example

### Measurement of Conductivity

(1) Each electrode was formed using metal paste compositions according to examples 1 to 5 and comparative example 1, and tested in aspects of conductivity.

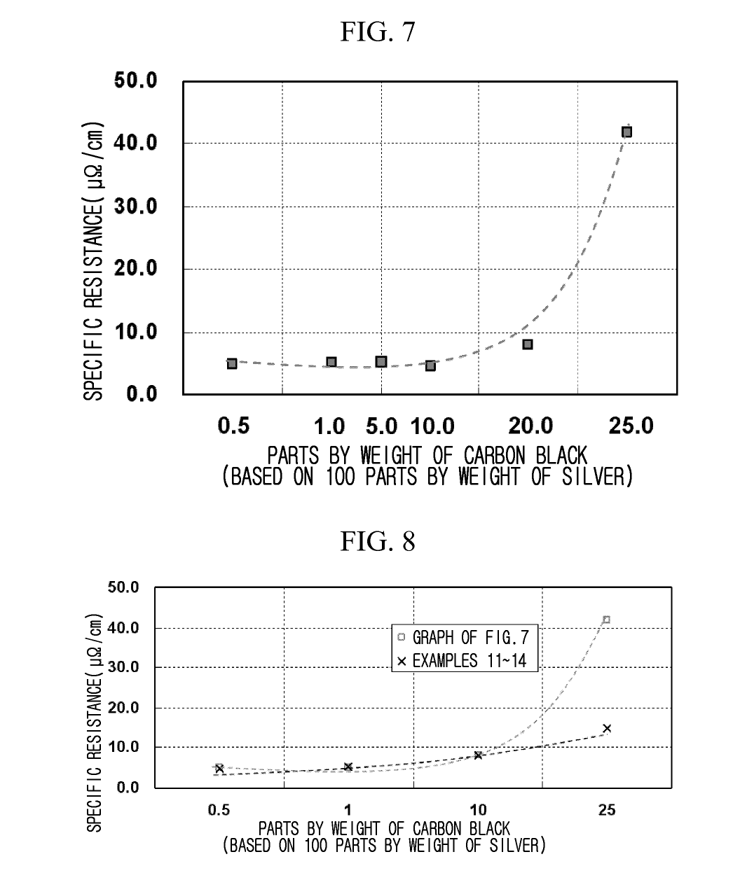

Specifically, the prepared metal paste composition was applied on a glass substrate by screen printing, and sintered at 650° C. for 5 minutes to form an electrode. A specific resistance of the electrode was measured by means of a 4-point probe. The measurement results are shown in FIG. 7.

Referring to FIG. 7, when 25 or more parts by weight of carbon black was added based on 100 parts by weight of silver having an average particle size of about 3 μm, a specific resistance of an electrode increased rapidly.

(2) Each electrode was formed using metal paste compositions according to examples 11 to 14, and tested in aspects of specific resistance. The measurement results are shown in FIG. 8.

Referring to FIG. 8, although a carbon-based material is included with the same content as examples 1 to 5, if an average particle size of silver exceeds 1 μm, a specific resistance of an electrode increased remarkably, resulting in an improper electrode.

### INDUSTRIAL APPLICABILITY

The metal paste composition for forming an electrode according to the present invention can reduce a usage amount of silver that is costly, while not deteriorating the electrical properties of a circuit or electrode.

Accordingly, an electrode formed using the metal paste composition of the present invention avoids deterioration in performance and has a reduced content of silver, thereby lowering the manufacturing costs of electrical products including the same.

1. A metal paste composition for forming an electrode, comprising glass frit powder, silver powder and an organic binder, the metal paste composition further comprising:
or less parts by weight of carbon-based material powder based on 100 parts by weight of the silver powder.

2. The metal paste composition for forming an electrode according to claim 1,
wherein the carbon-based material is at least one selected from the group consisting of graphite, carbon black, acetylene black, denka black, ketjen black, activated carbon, mesoporous carbon, carbon nano tube, carbon nano fiber, carbon nano horn, carbon nano ring, carbon nano wire, fullerene and Super-P.

3. The metal paste composition for forming an electrode according to claim 1,
wherein the glass frit powder includes lead oxide or bismuth oxide.

4. A metal paste composition for forming an electrode, comprising glass frit powder, silver powder and an organic binder, the metal paste composition further comprising:
or less parts by weight of carbon-based material powder based on 100 parts by weight of the silver powder,
wherein the silver powder has an average particle size of 1 μm or less.

5. The metal paste composition for forming an electrode according to claim 4,
wherein the carbon-based material is at least one selected from the group consisting of graphite, carbon black, acetylene black, denka black, ketjen black, activated carbon, mesoporous carbon, carbon nano tube, carbon nano fiber, carbon nano horn, carbon nano ring, carbon nano wire, fullerene and Super-P.

6. The metal paste composition for forming an electrode according to claim 4,
wherein the glass fit powder includes lead oxide or bismuth oxide.

7. A silver-carbon composite electrode, formed by sintering the metal paste composition defined in claim 1,
wherein the carbon-based material is dispersed in the electrode.

8. The silver-carbon composite electrode according to claim 7,
wherein the silver-carbon composite electrode has a specific resistance of 5 to 15 μΩ/cm at the electrode surface.

9. The silver-carbon composite electrode according to claim 7,
wherein a weight ratio of silver and carbon in the electrode is silver:carbon=1:0.001 to 1:0.25.

10. The silver-carbon composite electrode according to claim 7,
wherein the sintering temperature is 500 to 960° C.

11. A silicon solar cell, comprising:
a silicon semiconductor substrate;
an emitter layer formed on the substrate;
an antireflection film formed on the emitter layer;
a front electrode connected to the emitter layer through the antireflection film; and
a back electrode connected to a back surface of the substrate,
wherein the front electrode is formed by applying the metal paste composition defined in claim 1 on the antireflection film in a predetermined pattern and sintering the metal paste composition.
